(19) United States
(12) Patent Application Publication
(10) Pub. No.: US 2023/0341449 A1
(43) Pub. Date: Oct. 26, 2023

(54) DIGITAL FILTER AND MEASUREMENT INSTRUMENT

(71) Applicant: Rohde & Schwarz GmbH & Co. KG, Munich (DE)

(72) Inventors: Denis Petrovic, Munich (DE); Andreas Oeldemann, Munich (DE); Felix Haberstroh, Munich (DE); Nico Toender, Munich (DE); Cornelius Kaiser, Munich (DE)

(73) Assignee: Rohde & Schwarz GmbH & Co. KG, Munich (DE)

(21) Appl. No.: 17/727,371

(22) Filed: Apr. 22, 2022

(51) Int. Cl. G01R 23/167

(52) U.S. Cl. CPC G01R 23/167

(57) ABSTRACT

A digital filter for processing at least one input signal is described. The digital filter includes at least two filter parts that are separately formed from each other. The at least two filter parts are configured to process the at least one input signal in parallel which is received by the digital filter. A first filter part of the at least two filter parts is implemented in a first chip. A second filter part of the at least two filter parts is implemented in a second chip. Further, a measurement instrument is described.

### FIELD OF THE DISCLOSURE

Embodiments of the present disclosure generally relate to a digital filter for processing an input signal. Embodiments of the present disclosure further relate to a measurement instrument.

### BACKGROUND

In modern digital signal processing systems, e.g. in measurement instruments such as oscilloscopes, there is an increasing demand in hardware resources (multipliers, adders, memory) to implement digital filters. This is due to continuously increasing filter lengths and data path parallelism.

For example, the filter lengths have to be increased due to increasing ratios of maximum signal frequency and sampling frequency, increasing filter quality requirements, etc.

The data path parallelism may have to be increased due to increasing requirements on sampling rates, performance, and/or number of channels.

The increased hardware resource footprint results in a higher chip area, a higher power dissipation and a higher design complexity, which leads to higher costs of digital filters.

Thus, there is a need for a cost-effective digital filter being capable of providing a high filter length and a high data path parallelism.

### SUMMARY

Embodiments of the present disclosure provide a digital filter for processing at least one input signal. In an embodiment, the digital filter comprises at least two filter parts that are separately formed from each other. The at least two filter parts are configured to process the at least one input signal in parallel which is received by the digital filter. A first filter part of the at least two filter parts is implemented in a first chip. A second filter part of the at least two filter parts is implemented in a second chip.

Therein and in the following, the term “chip” is understood to denote an integrated circuit chip. In some embodiments, it is to be understood that a chip may comprise several cores, i.e. the individual chips may be established as multi-core chips, respectively. However, different cores of a single chip are not to be understood as different chips according to the present disclosure.

The digital filters described herein are based on the idea to split the digital filter into at least two different filter parts that are established separately from each other, wherein the at least two different filter parts are implemented in at least two different chips.

The digital filters set forth herein have several advantages described hereinafter. For example, the length of the digital filter can be increased in an easy manner by providing more chips, as the obtainable filter length scales linearly with the number of chips. Further, the data path parallelism of the digital filter can be increased in an easy manner by providing more chips, as the obtainable data path parallelism scales with the number of chips, for example wherein the obtainable data path parallelism scales linearly with the number of chips. Thus, the digital filters of the present disclosure can easily be adapted to provide a high filtering performance.

In some embodiments, distributing the filter parts across multiple chips can reduce the number of clock cycles required for filter calculations when time-multiplexing of hardware resources is performed. This increases the filter processing speed.

Moreover, the digital filter can be distributed among several smaller chips instead of having to be implemented on a single chip. Thus, the complexity of the individual chips can be reduced, which leads to an overall reduction in costs and an overall reduction in complexity.

As the digital filter can be distributed among several smaller chips, energy dissipation due to electric losses is distributed over a larger area as well. Thus, cooling systems for removing the dissipated energy can be implemented with reduced constraints, allowing for providing cooling systems with reduced cost and complexity.

Further, splitting the digital filter into several filter parts allows for optimizing the resource efficiency and/or the filter performance of each of the filter parts individually. For example, the individual filter parts can be optimized for short-length finite impulse response (FIR) filtering in time domain or for fast convolution in frequency domain, respectively.

According to an aspect of the present disclosure, the first chip, for example, is different from the second chip. In other words, the first chip and the second chip are physically different chips. For example, the first chip and the second chip may be spaced apart from each other by a predetermined distance.

According to another aspect of the present disclosure, the digital filter comprises, for example, a joint input interface, wherein the digital filter is configured to receive the at least one input signal via the joint input interface, and wherein the joint input interface is configured to forward the at least one input signal to the at least two filter parts.

If only a single input signal is received, the joint input interface may be configured to forward the single input signal to each of the at least two filter parts. In other words, each filter part may receive the same input data.

If at least two input signals are received, the joint input interface may be configured to forward the at least two input signals to each of the at least two filter parts. In other words, the joint input interface may be configured to forward each input signal to each filter part, such that each filter part receives the same input data.

Alternatively, if at least two input signals are received, the joint input interface may be configured to forward a first subset of the at least two input signals to the first filter part, and to forward a second subset of the at least two input signals to the second filter part.

The first subset and the second subset may be disjoint or may have an intersection. However, in this case the first subset and the second subset may not be identical. In other words, one or several input signals are forwarded to the first filter part, and one or several input signals are forwarded to the second filter part, but at least one of the filter parts does not receive at least one of the input signals.

In an embodiment of the present disclosure, the joint input interface comprises at least one delay circuit, wherein the at least one delay circuit is configured to phase-shift at least one of the at least one received input signal, thereby obtaining at least one phase-shifted input signal, and wherein the joint input interface is configured to forward the at least one phase-shifted input signal to at least one of the at least two filter parts. The at least one delay circuit ensures that the at least one input signal is processed correctly by the at least two filter parts. The at least one delay circuit ensures that output signals of the at least two filter parts are properly time-aligned. For example, the at least one delay circuit may take delays in the individual filter parts into account, and may provide an appropriate phase-shifted input signal to each filter part, such that the output signals of the at least two filter parts are properly time-aligned.

In a further embodiment of the present disclosure, the joint input interface comprises at least two signal inputs, such that the joint input interface is configured to receive at least two input signals. The at least two input signals may be associated with a single measurement channel of a measurement instrument or with different measurement channels of a measurement instrument.

In some embodiments, at least one filter part, i.e. at least one chip, may be provided for each measurement channel.

In other embodiments, the at least two input signals may correspond to different polyphases associated with a time-interleaved analog-to-digital converter (ADC).

The joint input interface may be configured to forward the at least two input signals to each of the at least two filter parts. In other words, the joint input interface may be configured to forward each input signal to each filter part.

Alternatively, if the at least two input signals are received, the joint input interface may be configured to forward a first subset of the at least two input signals to the first filter part, and to forward a second subset of the at least two input signals to the second filter part.

In some embodiments, the at least two filter parts are established as a finite impulse response (FIR) filter, respectively. By distributing the digital filter into the at least two FIR filters, a higher filter length, a long impulse response, increases data path parallelism, a higher signal to sample frequency ratio, a higher filter quality, a higher sampling rate and/or higher processing speed can be obtained, as already described above.

In some embodiments, each of the at least two filter parts may be established as a time-invariant FIR filter, respectively

Therein, each FIR filter, i.e. each of the at least two filter parts, may receive the same input data, i.e. the at least one input signal is forwarded to each of the at least two filter parts.

The different FIR filters may have the same filter length. Accordingly, a number N of filter parts each being established as a FIR filter may be provided, wherein each filter part may have a filter length l. Together, the N filter parts establish an overall FIR filter, namely the digital filter, having a filter length of L=N·l.

However, the different FIR filters may also have different filter lengths. Accordingly, a number N of filter parts each being established as a FIR filter may be provided, wherein each filter part may have a filter length l. Together, the N filter parts establish an overall FIR filter, namely the digital filter, having a filter length of L=Σᵢlᵢ.

Thus, large total filter lengths L can be obtained by one or more of the digital filters according to the present disclosure, which may be very costly and complex to obtain with usual digital filters being implemented in a single chip.

According to an aspect of the present disclosure, the at least two filter parts are established as, for example, at least one of a low-pass filter, a high-pass filter, a band-pass filter, a de-embedding filter, or an equalization filter, respectively. However, it is to be understood that the at least two filters may be established as any other type of filter.

According to a further aspect of the present disclosure, the at least two filter parts are established as, for example, a polyphase filter, respectively. For example, the digital filter may be used in conjunction with a time-interleaved ADC, and may be configured to compensate alignment mismatches of the time-interleaved ADC.

Thus, some embodiments of the digital filter may be configured to receive a plurality of input signals corresponding to a plurality of polyphases. Embodiments of these digital filters may further be configured to process the plurality of input signals, thereby generating a plurality of output signals. Thus, these digital filters may be established as multiple input multiple output filters.

In some embodiments, the digital filter may be configured to receive P input signal, wherein P is an integer greater than or equal to 2.

Some embodiments of the digital filter may comprise a total of P² polyphase filters, wherein the P² polyphase filters are distributed over N filter parts, i.e. over N chips. Thus, each chip or each filter part may comprise P²/N polyphase filters.

Accordingly, P/N input signals may be forwarded to each of the filter parts.

Together, the N filter parts provide an overall polyphase filter, namely the digital filter, being configured to process all P polyphases.

In some embodiments, each polyphase filter may have a predetermined filter length L.

Thus, processing of the plurality of input signals is distributed over the N chips.

It has turned out that the number of clock cycles required for filter calculation when time-multiplexing of hardware resources is performed can be reduced, which increases the filter processing speed.

In an embodiment of the present disclosure, the digital filter comprises a joint output interface, wherein the joint output interface is configured to combine output signals of the at least two filter parts, thereby obtaining at least one combined output signal. In general, the output interface is configured to recombine output signals of the individual filter parts in order to obtain an overall output signal or a plurality of overall output signals of the digital filter.

For example, the output interface may comprise an adder sub-circuit, wherein the adder sub-circuit is configured to sum the output signals of the at least two filter parts.

The joint output interface may comprise at least one delay circuit, wherein the at least one delay circuit is configured to phase-shift at least one of the output signals of the at least two filter parts. The at least one delay circuit ensures that the at least one input signal is processed correctly by means of the at least two filter parts. In some embodiments, the at least one delay circuit ensures that output signals of the at least two filter parts are properly time-aligned. For example, the at least one delay circuit may take delays in the individual filter parts into account, and may provide an appropriate phase-shift to the output signals of the filter parts, such that the output signals of the at least two filter parts are properly time-aligned.

In an embodiment of the present disclosure, the joint output interface comprises at least two signal outputs, such that the joint output interface is configured to provide at least two overall output signals. The at least two output signals may be associated with a single measurement channel of a measurement instrument or with different measurement channels of a measurement instrument.

For example, the at least two overall output signals may correspond to different polyphases associated with a time-interleaved analog-to-digital converter (ADC).

In some embodiments, the digital filter may comprise a joint input interface with at least two signal inputs, and a joint output interface with at least two signal outputs. Thus, the digital filter may be established as a multiple input multiple output filter.

The number of signal inputs may match the number of signal outputs. However, it is also conceivable that the number of signal inputs is greater or smaller than the number of signal outputs.

In some embodiments, the joint output interface comprises a synchronization memory, wherein the synchronization memory is configured to synchronize the output signals of the at least two filter parts. Thus, it is ensured that the individual parts (i.e. the output signals of the at least two filter parts) of one or several overall outputs signals of the digital filter are properly aligned. In other words, runtime differences or clock differences between the at least two filter parts can be compensated by the synchronization memory.

The synchronization memory may be established as a first in first out (FIFO) memory. Thus, the individual parts of the one or several parts of the overall output signal(s) are output consecutively, but in a time-aligned manner. Thus, runtime differences or clock differences between the at least two filter parts are compensated.

According to an aspect of the present disclosure, the digital filter comprises, for example, N filter parts, wherein N is an integer greater than or equal to 3. In some embodiments, the digital filter can be scaled arbitrarily by providing additional filter parts being implemented on additional chips. In other words, the number N can easily be adapted for different types of applications having different requirements on the digital filter.

In an embodiment of the present disclosure, the at least two filter parts together realize a single overall filter functionality. In other words, the at least two filter parts work together to provide the overall filter functionality by processing the at least one input signal in parallel.

For example, a low-pass filter, a high-pass filter, a band-pass filter, a de-embedding filter, an equalization filter, and/or a polyphase filter may be provided by the filter parts processing the at least one input signal in parallel.

Embodiments of the present disclosure further provide a measurement instrument. In an embodiment, the measurement instrument comprises a digital filter for processing at least one input signal, wherein the digital filter comprises at least two filter parts that are separately formed from each other. The at least two filter parts are configured to process the at least one input signal in parallel which is received by the digital filter. A first filter part of the at least two filter parts is implemented in a first chip of the measurement instrument. A second filter part of the at least two filter parts is implemented in a second chip of the measurement instrument.

In some embodiments, the measurement instrument comprises a digital filter according to any of the embodiments described above.

Regarding the advantages and further properties of the measurement instrument, reference is made to the explanations given above with respect to the digital filter, which also hold for the measurement instrument and vice versa.

According to an aspect of the present disclosure, the measurement instrument is established as a digital oscilloscope, as a signal analyzer, as a spectrum analyzer, or as a vector network analyzer. However, it is to be understood that the digital filter may be used in any other type of measurement instrument being configured to process digital signals, or in any other type of electronic device being configured to process digital signals.

The measurement instrument may comprise at least one measurement input, wherein the measurement instrument comprises a signal processing circuit and/or an acquisition circuit connected to the at least one measurement input, wherein the digital filter is integrated into the acquisition circuit or into the signal processing circuit.

For example, the acquisition circuit may comprise at least one time-interleaved ADC being configured to sample at least one measurement signal received via the measurement input in a time-interleaved manner. The digital filter may be provided downstream of the at least one time-interleaved ADC, and may be configured to compensate alignment mismatches of the at least one time-interleaved ADC, as described above.

As another example, the digital filter may be provided in the signal processing circuit or in the acquisition circuit and may be configured to provide a certain filter functionality, for example a low-pass filter, a high-pass filter, a band-pass filter, a de-embedding filter, and/or an equalization filter.

In an embodiment of the present disclosure, the measurement instrument comprises at least two measurement channels, wherein the digital filter is associated with both of the at least two measurement channels. Thus, the digital filter may be configured to process signals associated with the at least two measurement channels in parallel by the at least two filter parts.

In some embodiments, the digital filter is configured to at least one of compensate time delays between the at least two measurement channels, compensate alignment mismatches between the at least two measurement channels, equalize signals processed by the at least two measurement channels, or filter out predetermined frequencies from signals processed by the at least two measurement channels.

However, it is to be understood that the digital filters of the present disclosure may provide any other filter functionality that is needed for a particular measurement application.

### DESCRIPTION OF THE DRAWINGS

The foregoing aspects and many of the attendant advantages of the claimed subject matter will become more readily appreciated as the same become better understood by reference to the following detailed description, when taken in conjunction with the accompanying drawings, wherein:

FIG. 1 schematically shows a measurement instrument according to an embodiment of the present disclosure;

FIG. 2 schematically shows an embodiment of a digital filter according to the present disclosure; and

FIG. 3 schematically shows another embodiment of digital filter according to the present disclosure.

### DETAILED DESCRIPTION

The detailed description set forth below in connection with the appended drawings, where like numerals reference like elements, is intended as a description of various embodiments of the disclosed subject matter and is not intended to represent the only embodiments. Each embodiment described in this disclosure is provided merely as an example or illustration and should not be construed as preferred or advantageous over other embodiments. The illustrative examples provided herein are not intended to be exhaustive or to limit the claimed subject matter to the precise forms disclosed.

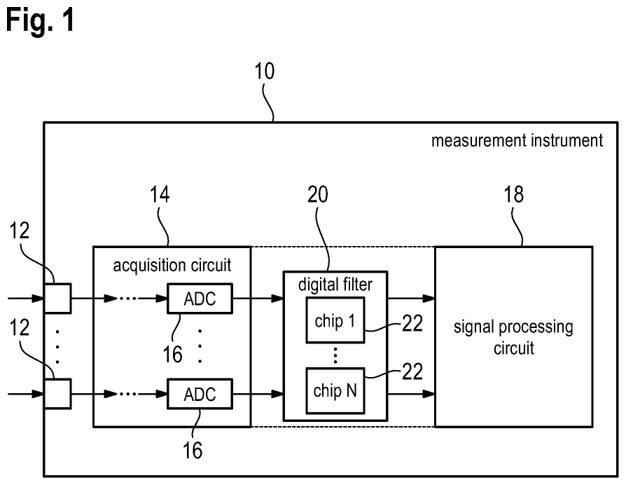

FIG. 1 schematically shows a measurement instrument 10 in accordance with an embodiment of the present disclosure. For example, the measurement instrument 10 may be established as a digital oscilloscope, as a signal analyzer, as a spectrum analyzer, or as a vector network analyzer. However, the measurement instrument 10 may be established as any other type of measurement instrument being configured to process digital signals.

Without restriction of generality, it is assumed in the following that the measurement instrument 10 is established as a digital oscilloscope.

As shown in FIG. 1, the measurement instrument 10 comprises one or several measurement inputs 12 that are configured to receive one or several analog measurement signals, for example from a device under test. The measurement inputs 12 may correspond to different measurement channels of the measurement instrument 10.

The measurement instrument 10 further comprises an acquisition circuit 14 that is connected to measurement inputs 12 downstream of the measurement inputs 12. In general, the acquisition circuit 14 is configured to receive and pre-process the one or several analog measurement signals, such that the pre-processed measurement signal(s) can be appropriately processed by further electronic components of the measurement instrument 10.

Among other acquisition circuitry (indicated by the dots in FIG. 1), the acquisition circuit comprises at least one analog-to-digital converter (ADC) 16 that is configured to digitize the measurement signal(s) received via the measurement input(s) 12. In some embodiments, the acquisition circuit 14 may comprise an ADC 16 for each measurement input 12. Alternatively, a single ADC 16 may be configured to digitize several measurement signals. Alternatively, several ADCs 16 may be configured to digitize a single measurement signal in a time-interleaved manner.

In order to achieve particularly high sampling rates, the at least one ADC 16 may be established as a time-interleaved ADC, i.e. the at least one ADC 16 may be configured to sample the measurement signal(s) in a time-interleaved manner.

The acquisition circuit 14 may further comprise an acquisition memory being connected to the at least one ADC 16, wherein the acquisition memory is configured to save the signal(s) digitized by the at least one ADC 16 at least temporarily. For example, the acquisition memory may be established as a ring memory, also called “ring buffer”.

It is noted that the digitized signals may be forwarded to components downstream of the acquisition circuit 14 by the at least one ADC 16, by the acquisition memory, or by other electronic components of the acquisition circuit 14.

Without restriction of generality, it is assumed in the following that the at least one ADC 16 directly forwards the at least one digitized signal.

The measurement instrument 10 further comprises a signal processing circuit 18 downstream of the acquisition circuit 14. In general, the signal processing circuit is configured to process the digitized signal(s) provided by the at least one ADC 16 in order to analyze certain properties of the measurement signal(s) received.

In some embodiments, a plurality of different measurement functionalities may be provided, depending on the type of the measurement instrument 10. These measurement functionalities correspond to the measurement functionalities provided by measurement instruments known in the state of the art, and will thus not be described in more detail hereinafter.

The measurement instrument further comprises a digital filter 20 that is provided downstream of the at least one ADC 16. In the exemplary embodiment shown in FIG. 1, the digital filter 20 is interconnected between the acquisition circuit 14 and the signal processing circuit 18. However, as is indicated by the dashed lines in FIG. 1, the digital filter 20 may also be integrated into the acquisition circuit 14 or into the signal processing circuit 18, depending on the filter functionality provided by the digital filter 20.

Irrespective of the particular filter functionality provided by the digital filter 20, the digital filter comprises N filter parts that are separately formed from each other, wherein N is an integer greater than or equal to 2. Each of the N filter parts is implemented on a different chip 22, such that the N filter parts are implemented in N different chips 22, i.e. in N physically different chips 22. Therein and in the following, the term “chip” is understood to denote an integrated circuit chip.

In some embodiments, it is to be understood that a chip may comprise several cores, i.e. the individual chips 22 may be established as multi-core chips, respectively. However, different cores of a single chip 22 are not to be understood as different chips according to the present disclosure. For example, the different chips 22 may be spaced apart from each other by a predetermined distance, respectively.

In general, the N filter parts are configured to process the one or several digitized signals provided by the at least one ADC 16 in parallel, wherein the N filter parts together realize a single overall filter functionality. For example, a low-pass filter, a high-pass filter, a band-pass filter, a de-embedding filter, an equalization filter, and/or a polyphase filter may be provided by the filter parts processing the at least one input signal in parallel.

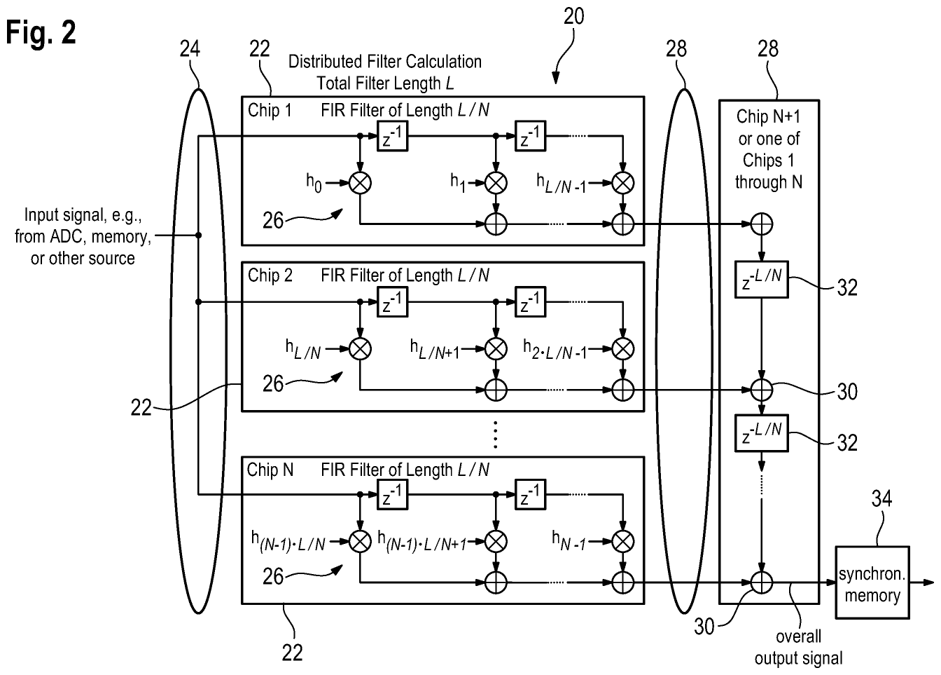

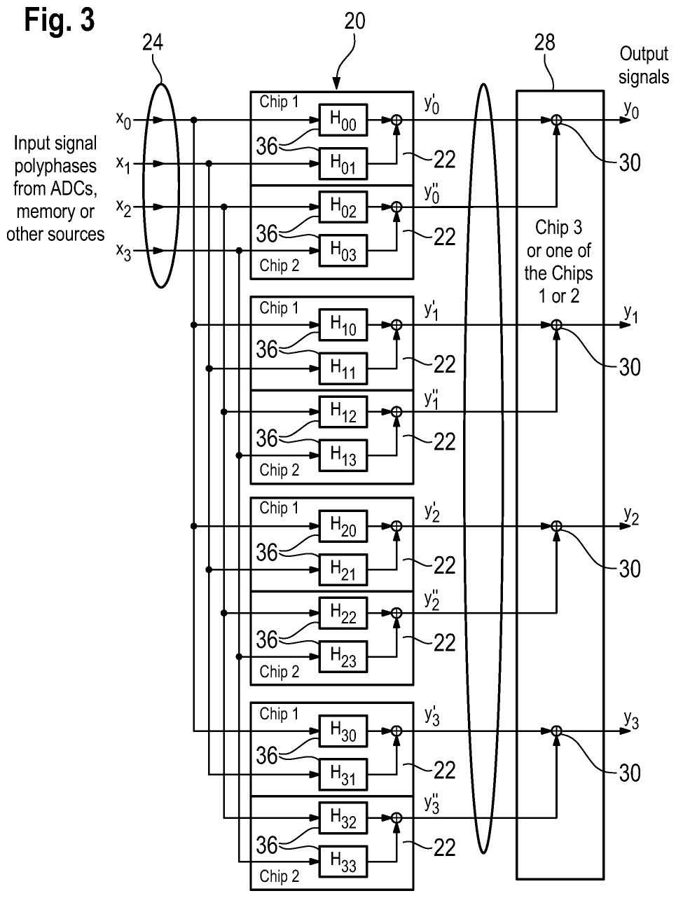

The functionality of the digital filter 20 will be explained in more detail in the following with respect to two representative embodiments shown in FIGS. 2 and 3.

FIG. 2 shows a first representative embodiment of the digital filter 20. In this embodiment, the digital filter 20 is established as a finite impulse response (FIR) filter having a total filter length L. For example, the digital filter 20 of FIG. 2 may be a low-pass filter, a high-pass filter, a band-pass filter, a de-embedding filter, and/or an equalization filter.

The digital filter 20 comprises a joint input interface 24 being connected to each of the chips 22 upstream of the chips 22. The joint input interface 24 is configured to receive at least one input signal, e.g. from the at least one ADC 16 or from another electronic component of the acquisition circuit 14, or from another electronic circuit of the measurement instrument 10.

The joint input interface 24 is further configured to forward the at least one input signal to all N filter parts, i.e. to all N chips 22. In other words, each of the N chips 22 receives the same input data.

In the embodiment shown, the different filter parts are established as an FIR filter 26, respectively, for example as a time-invariant FIR filter 26. The different FIR filters 26 may have the same filter length. Accordingly, a number N of filter parts each being established as a FIR filter may be provided, wherein each filter part may have a filter length l. Together, the N filter parts establish an overall FIR filter, namely the digital filter 20, having a filter length of L=N l.

However, the different FIR filters 26 in other embodiments may also have different filter lengths. Accordingly, a number N of filter parts each being established as a FIR filter may be provided, wherein each filter part may have a filter length l. Together, the N filter parts establish an overall FIR filter, namely the digital filter, having a filter length of L=Σᵢlᵢ.

As shown in FIG. 2, the digital filter 20 further comprises a joint output interface 28 being connected to each of the chips 22 downstream of the chips 22. The joint output interface 28 may at least partially be implemented on one of the N chips 22, or in a separate chip, i.e. on a (N+1) chip.

In general, the joint output interface 28 is configured to combine output signals of the different filter parts, thereby obtaining at least one combined output signal, i.e. an overall output signal of the digital filter 20. In some embodiments, the joint output interface 28 comprises at least one adder sub-circuit 30, for example a plurality of adder sub-circuit 30, wherein the at least one adder sub-circuit 30 is configured to sum the output signals of the different filter parts, thereby obtaining the overall output signal of the digital filter 20.

The joint output interface 28 may further comprise at least one delay circuit 32, wherein the at least one delay circuit 32 is configured to phase-shift at least one of the output signals of the different filter parts. It is noted that the at least one delay circuit 32 may alternatively be integrated into the joint input interface 24. The functionality of the at least one delay circuit 32 remains unchanged.

The at least one delay circuit 32 ensures that the at least one input signal is processed correctly by the different filter parts. More precisely, the at least one delay circuit 32 ensures that output signals of the different filter parts are properly time-aligned. For example, the at least one delay circuit 32 may take delays in the individual filter parts into account, and may provide an appropriate phase-shift to the output signals of the different filter parts, such that the output signals of different filter parts are properly time-aligned.

Alternatively or additionally, the joint output interface 28 may comprise a synchronization memory 34, wherein the synchronization memory 34 is configured to synchronize the output signals of the different filter parts. In other words, the synchronization memory ensures that the individual parts (i.e. the output signals of the different filter parts) of the overall outputs signal of the digital filter 20 are properly aligned.

Accordingly, runtime differences or clock differences between the different filter parts can be compensated by the synchronization memory 34 and/or by the at least one delay circuit 32.

The synchronization memory 34 may be established as a first in first out (FIFO) memory. Thus, the individual parts of the overall output signal(s) are output consecutively, but in a time-aligned manner. Thus, runtime differences or clock differences between the different filter parts are compensated.

FIG. 3 shows a second representative embodiments of the digital filter 20, wherein only the differences compared to the exemplary embodiment of FIG. 2 are described in the following. In this embodiment, the digital filter 20 is established as a polyphase filter.

For example, the digital filter 20 may be used in conjunction with time-interleaved ADC(s) 16, and may be configured to compensate alignment mismatches of the time-interleaved ADC(s) 16.

It is noted that FIG. 3 shows a particular example for N=2, i.e. for two different filter parts being implemented on two different chips 22. However, more than two filter parts being implemented on more than two chips 22 may be provided.

In general, the joint input interface is configured to receive a plurality of input signals xᵢ, namely P input signals xᵢ corresponding to P different polyphases, e.g. P different polyphases of time-interleaved ADC(s) 16.

The digital filter 20 comprises a total of P² polyphase filters 36, wherein the P² polyphase filters 36 are distributed over N filter parts, i.e. over N chips 22. Thus, each chip 22 or each filter part may comprise P²/N polyphase filters 36. Each polyphase filter 36 may have a filter length L.

Further, P/N input signals xᵢ of the total of P input signals xᵢ are forwarded to each of the filter parts by the joint input interface 24, i.e. different input signals xᵢ are forwarded to the different filter parts. In the particular example shown in FIG. 3, four input signals xᵢ and two chips 22 are provided, such that each filter part comprises eight polyphase filters 36. Two input signals xᵢ are forwarded to each of the two chips 22, i.e. to each of the two filter parts. More precisely, input signals x₀ and x₁ are forwarded to “Chip 1”, i.e. to a first filter part, while input signals x₂ and x₃ are forwarded to “Chip 2”, i.e. to a second filter part.

The joint output interface 28 is configured to combine output signals of the different filter parts, thereby obtaining a plurality of output signals yᵢ, i.e. a plurality of overall output signals of the digital filter 20. In some embodiments, the joint output interface 28 comprises a plurality of adder sub-circuits 30, wherein the plurality of adder sub-circuits 30 is configured to appropriately sum certain subsets of the output signals of the different filter parts, namely output signals yᵢ′ and yᵢ″, thereby obtaining the plurality of overall output signals yᵢ of the digital filter 20.

Accordingly, the digital filter 20 is configured to process the plurality of input signals xᵢ, thereby generating the plurality of output signals yᵢ. Thus, the digital filter 20 is established as a multiple input multiple output filter.

In the embodiment shown in FIG. 3, the number of output signals yᵢ matches the number of input signals xᵢ. However, it is also conceivable that the number of input signals xᵢ may be greater or smaller than the number of output signals yᵢ.

Certain embodiments disclosed herein utilize circuitry (e.g., one or more circuits) in order to implement protocols, methodologies or technologies disclosed herein, operably couple two or more components, generate information, process information, analyze information, generate signals, encode/decode signals, convert signals, transmit and/or receive signals, control other devices, etc. Circuitry of any type can be used. It will be appreciated that the term “information” can be use synonymously with the term “signals” in this paragraph. It will be further appreciated that the terms “circuitry,” “circuit,” “one or more circuits,” etc., can be used synonymously herein.

In an embodiment, circuitry includes, among other things, one or more computing devices such as a processor (e.g., a microprocessor), a central processing unit (CPU), a digital signal processor (DSP), an application-specific integrated circuit (ASIC), a field programmable gate array (FPGA), a system on a chip (SoC), or the like, or any combinations thereof, and can include discrete digital or analog circuit elements or electronics, or combinations thereof.

In an embodiment, circuitry includes hardware circuit implementations (e.g., implementations in analog circuitry, implementations in digital circuitry, and the like, and combinations thereof). In an embodiment, circuitry includes combinations of circuits and computer program products having software or firmware instructions stored on one or more computer readable memories that work together to cause a device to perform one or more protocols, methodologies or technologies described herein. In an embodiment, circuitry includes circuits, such as, for example, microprocessors or portions of microprocessor, that require software, firmware, and the like for operation. In an embodiment, circuitry includes an implementation comprising one or more processors or portions thereof and accompanying software, firmware, hardware, and the like.

The present application may reference quantities and numbers. Unless specifically stated, such quantities and numbers are not to be considered restrictive, but exemplary of the possible quantities or numbers associated with the present application. Also in this regard, the present application may use the term “plurality” to reference a quantity or number. In this regard, the term “plurality” is meant to be any number that is more than one, for example, two, three, four, five, etc. The terms “about,” “approximately,” “near,” etc., mean plus or minus 5% of the stated value. For the purposes of the present disclosure, the phrase “at least one of A and B” is equivalent to “A and/or B” or vice versa, namely “A” alone, “B” alone or “A and B.”. Similarly, the phrase “at least one of A, B, and C,” for example, means (A), (B), (C), (A and B), (A and C), (B and C), or (A, B, and C), including all further possible permutations when greater than three elements are listed.

The principles, representative embodiments, and modes of operation of the present disclosure have been described in the foregoing description. However, aspects of the present disclosure which are intended to be protected are not to be construed as limited to the particular embodiments disclosed. Further, the embodiments described herein are to be regarded as illustrative rather than restrictive. It will be appreciated that variations and changes may be made by others, and equivalents employed, without departing from the spirit of the present disclosure. Accordingly, it is expressly intended that all such variations, changes, and equivalents fall within the spirit and scope of the present disclosure, as claimed.

1. A digital filter for processing at least one input signal, comprising:
at least two filter parts that are separately formed from each other, the at least two filter parts being configured to process the at least one input signal in parallel which is received by the digital filter, wherein a first filter part of the at least two filter parts is implemented in a first chip, and wherein a second filter part of the at least two filter parts is implemented in a second chip.

2. The digital filter of claim 1, wherein the first chip is different from the second chip.

3. The digital filter of claim 1, further comprising a joint input interface, wherein the digital filter is configured to receive the at least one input signal via the joint input interface, and wherein the joint input interface is configured to forward the at least one input signal to the at least two filter parts.

4. The digital filter of claim 3, wherein the joint input interface comprises at least one delay circuit, wherein the at least one delay circuit is configured to phase-shift at least one of the at least one received input signal, thereby obtaining at least one phase-shifted input signal, and wherein the joint input interface is configured to forward the at least one phase-shifted input signal to at least one of the at least two filter parts.

5. The digital filter of claim 3, wherein the joint input interface comprises at least two signal inputs, such that the joint input interface is configured to receive at least two input signals.

6. The digital filter of claim 1, wherein the at least two filter parts are established as a finite impulse response (FIR) filter, respectively.

7. The digital filter of claim 6, wherein the at least two filter parts are established as at least one of a low-pass filter, a high-pass filter, a band-pass filter, a de-embedding filter, or an equalization filter, respectively.

8. The digital filter of claim 1, wherein the at least two filter parts are established as a polyphase filter, respectively.

9. The digital filter of claim 1, wherein the digital filter comprises a joint output interface, wherein the joint output interface is configured to combine output signals of the at least two filter parts, thereby obtaining at least one combined output signal.

10. The digital filter of claim 9, wherein the joint output interface comprises at least one delay circuit, wherein the at least one delay circuit is configured to phase-shift at least one of the output signals of the at least two filter parts.

11. The digital filter of claim 9, wherein the joint output interface comprises at least two signal outputs, such that the joint output interface is configured to provide at least two overall output signals.

12. The digital filter of claim 9, wherein the joint output interface comprises a synchronization memory, wherein the synchronization memory is configured to synchronize the output signals of the at least two filter parts.

13. The digital filter of claim 12, wherein the synchronization memory is established as a first in first out (FIFO) memory.

14. The digital filter of claim 1, further comprising N filter parts, wherein N is an integer greater than or equal to 3.

15. The digital filter of claim 1, wherein the at least two filter parts together realize a single overall filter functionality.

16. A measurement instrument, comprising:
a digital filter for processing at least one input signal, wherein the digital filter comprises at least two filter parts that are separately formed from each other,
wherein the at least two filter parts are configured to process the at least one input signal in parallel which is received by the digital filter,
wherein a first filter part of the at least two filter parts is implemented in a first chip of the measurement instrument, and
wherein a second filter part of the at least two filter parts is implemented in a second chip of the measurement instrument.

17. The measurement instrument of claim 16, wherein the measurement instrument is established as a digital oscilloscope, as a signal analyzer, as a spectrum analyzer, or as a vector network analyzer.

18. The measurement instrument of claim 16, wherein the measurement instrument comprises at least one measurement input, wherein the measurement instrument comprises a signal processing circuit and/or an acquisition circuit connected to the at least one measurement input, wherein the digital filter is integrated into the acquisition circuit or into the signal processing circuit.

19. The measurement instrument of claim 16, wherein the measurement instrument comprises at least two measurement channels, wherein the digital filter is associated with both of the at least two measurement channels.

20. The measurement instrument of claim 19, wherein the digital filter is configured to at least one of compensate time delays between the at least two measurement channels, compensate alignment mismatches between the at least two measurement channels, equalize signals processed by the at least two measurement channels, or filter out predetermined frequencies from signals processed by the at least two measurement channels.
